(19) United States
(12) Patent Application Publication
(10) Pub. No.: US 2026/0068667 A1
(43) Pub. Date: Mar. 5, 2026

(54) SEMICONDUCTOR PACKAGE STRUCTURE AND METHOD FOR FORMING THE SAME

(71) Applicant: TAIWAN SEMICONDUCTOR MANUFACTURING COMPANY LTD., HSINCHU (TW)

(72) Inventors: MING-HSIEN LIN, HSINCHU (TW); KUN-YEN LIAO, TAIPEI CITY (TW)

(21) Appl. No.: 18/824,977

(22) Filed: Sep. 5, 2024

(51) Int. Cl. H01L 23/373; H01L 23/00; H01L 23/48

(52) U.S. Cl. CPC H01L 23/3733

(57) ABSTRACT

A semiconductor package structure includes a first package component, a second package component disposed over the first package component, a plurality of connectors between the first package component and the second package component, an underfill between the first package component and the second package component and surrounding the plurality of connectors, and a plurality of heat sink fibers in the underfill. A thermal conductivity of the plurality of heat sink fibers is greater than a thermal conductivity of the underfill.

### BACKGROUND

Greater densities of electronic components may be achieved by fabricating three-dimensional (3D) integrated circuit (IC) device structures. One of typical issues with the 3D ID device structure is heat dissipation. A prolonged exposure of a die at high temperature during operation may decrease the reliability and operation lifetime of the die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor package structure in accordance with aspects of the present disclosure in one or more embodiments.

FIG. 2 is a schematic cross-sectional view of a semiconductor package structure in accordance with aspects of the present disclosure in one or more embodiments.

FIG. 3 is a schematic cross-sectional view of a semiconductor package structure in accordance with aspects of the present disclosure in one or more embodiments.

FIG. 4 is a schematic cross-sectional view of a semiconductor package structure in accordance with aspects of the present disclosure in one or more embodiments.

FIGS. 5A to 5D are cross-sectional views of various stages in a formation of a semiconductor package structure in accordance with aspects of the present disclosure in one or more embodiments.

FIGS. 6A to 6F are cross-sectional views of various stages in a formation of a semiconductor package structure in accordance with aspects of the present disclosure in one or more embodiments.

FIGS. 7A to 7I are cross-sectional views of various stages in a formation of a semiconductor package structure in accordance with aspects of the present disclosure in one or more embodiments.

FIGS. 8A to 8C are schematic drawings illustrating a formation of heat sink fibers in an underfill in accordance with aspects of the present disclosure in one or more embodiments.

FIGS. 9A to 9C are schematic drawings illustrating a formation of heat sink fibers in an underfill in accordance with aspects of the present disclosure in one or more embodiments.

FIGS. 10A, 10B1 and 10B2 are schematic drawings illustrating a formation of heat sink fibers in an underfill in accordance with aspects of the present disclosure in one or more embodiments.

FIGS. 11A to 11F are schematic drawings illustrating a formation of heat sink fibers in an underfill in accordance with aspects of the present disclosure in one or more embodiments.

FIG. 12 is a diagram illustrating a simulation of a thermal resistance and a density of heat sink fibers in an underfill in accordance with aspects of the present disclosure in one or more embodiment.

FIG. 13 is a flowchart representing a method for forming a semiconductor package structure in accordance with aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective test measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about. ” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

To achieve greater computing efficiency, wider data bandwidth, greater functionality packaging density, lower communication latency, and lower energy consumption per bit of data, system on integrated chips (SoIC) has been developed as a 3D packaging solution. This approach integrates active and passive chips into an integrated SoIC system to meet ever-increasing market demands. However, 3D packaging poses challenges, including those related to thermal management, power delivery, and yield, that need to be overcome.

In some approaches, underfill, a type of adhesive material, is used in semiconductor packaging. The underfill may be applied to a gap between a die and a substrate of a packaged integrated circuit, and help to distribute stress and improve reliability of the package structure by bonding the die to the substrate. The underfill may include a material having properties of at least: (1) low coefficient of thermal expansion (CTE); (2) high glass transition temperature (Tg); and (3) good flow characteristics. Such properties ensure that the underfill flows easily into the narrow gaps between the die and the substrate, filling voids and ensuring a good bond. However, materials having such properties may also have low thermal conductivity ranging from, for example but not limited thereto, approximately 0.1 W/mK to 1 W/mK. Such low thermal conductivity may incur or exacerbate a dissipation issue in the package structure.

In accordance with some embodiments, the present disclosure provides a scheme for improve heat dissipation in semiconductor package structures and methods of forming the semiconductor package structures. In some embodiments, heat sink fibers are provided and embedded in an underfill. The heat sink fibers include material having a thermal conductivity greater than that of the underfill and thus serves as dissipation paths. Accordingly, heat can be dissipated through the heat sink fibers and thus heat dissipation of the semiconductor package structure is improved.

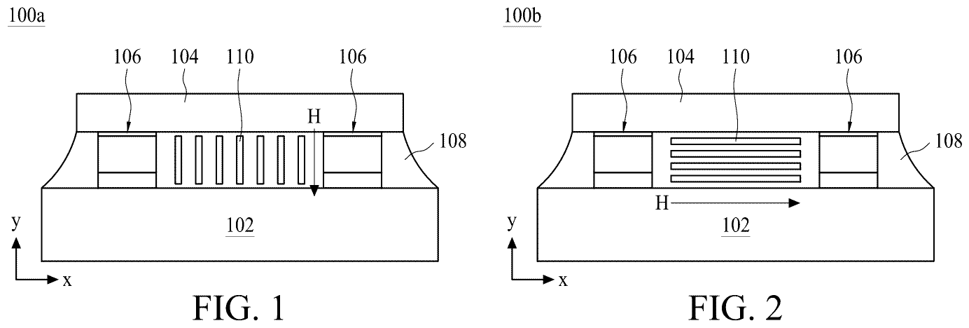

FIGS. 1 to 4 are schematic cross-sectional views of a semiconductor package structure in accordance with aspects of the present disclosure in various embodiments. In FIGS. 1 to 4, similar elements are designated by same numerals. In accordance with some embodiments, the semiconductor package structures 100a, 100b, 100c and 100d are provided as shown in FIGS. 1 to 4. Each of the semiconductor package structures 100a, 100b, 100c and 100d includes a package component. In some embodiments, the package component may be a semiconductor die. In other embodiments, the package component may be a substrate 102. In some embodiments, the substrate 102 may be a semiconductor substrate that is defined to mean any construction including semiconductor materials, including, but not limited to, bulk silicon, a semiconductor wafer, a silicon-on-insulator (SOI) substrate, or a silicon germanium substrate. Other semiconductor materials including group III, group IV, and group V elements may also be used. The substrate 102 may further include a plurality of isolation features (not shown), such as shallow trench isolation (STI) features or local oxidation of silicon (LOCOS) features formed in the substrate 102. The isolation features may define and isolate active regions in the substrate 102. Various microelectronic elements may be formed in or over an active surface of the substrate 102. The various microelectronic elements include active and passive devices such as transistors (e.g., metal-oxide-semiconductor field-effect transistors (MOSFET), complementary metal-oxide-semiconductor (CMOS) transistors, bipolar junction transistors (BJT), high-voltage transistors, high-frequency transistors, p-channel and/or n-channel field-effect transistors (PFETs/NFETs), etc.); resistors; diodes; capacitors; inductors; fuses; and other suitable elements. Various processes are performed to form the various microelectronic elements including deposition, etching, implantation, photolithography, annealing, and other suitable processes.

In some embodiments, alternating layers of conductive materials (such as copper, aluminum, alloys, doped polysilicon, combinations thereof, or the like) may be utilized between layers of dielectric material to form interconnections between the active and passive devices and also to provide access to external elements connected to the substrate 102. In some embodiments, through substrate vias (TSVs) may also be formed in order to provide electrical connectivity from the active surface to a backside surface that is opposite to the active surface, though not shown.

The semiconductor package structures 100a, 100b, 100c and 100d respectively includes a package component 104 disposed over the substrate 102. The package component 104 may include a semiconductor die, semiconductor dies or stacked semiconductor dies that can work in conjunction with the substrate 102 to provide a desired functionality. The package component 104 may have a single function (e.g., a logic device die, memory die, etc.) or multiple functions (e.g., a system on chip (SoC)).

Each of the semiconductor package structures 100a, 100b, 100c and 100d includes a plurality of connectors 106 between the substrate 102 and the package component 104. The connectors 106 physically and electrically couple the package component 104 to the substrate 102. In some embodiments, the connectors 106 may be formed from a conductive material such as solder, copper, aluminum, gold, nickel, silver, palladium, tin, the like, or a combination thereof.

Each of the semiconductor package structures 100a, 100b, 100c and 100d includes an underfill 108 between the substrate 102 and the package component 104. Further, the underfill 108 surrounds the connectors 106. As shown in FIGS. 1 to 4, the underfill 108 fills gaps between the connectors 106, the package component 104 and the substrate 102. The underfill 108 helps to secure the connectors 106, obstruct moistures, and improve mechanical reliability. In some embodiments, a thermal conductivity of the underfill 108 is less than 1 W/mK. For example but not limited thereto, the thermal conductivity of the underfill 108 may be between approximately 0.1 W/mK and approximately 1 W/mK. In some embodiments, the underfill 108 may include epoxy resin, but the disclosure is not limited thereto.

Each of the semiconductor package structures 100a, 100b, 100c and 100d includes a plurality of heat sink fibers 110 disposed in the underfill 108. A thermal conductivity of the heat sink fibers 110 is greater than the thermal conductivity of the underfill 108. For example but not limited thereto, the thermal conductivity of the heat sink fibers 110 may be between approximately 1.5 W/mK and approximately 100 W/mK. In some embodiments, the heat sink fibers 110 include conductive materials. In some embodiments, the heat sink fibers 110 include 2D materials. In some embodiments, the heat sink fibers 110 include diamond, boron nitride (BN), boron phosphide (BP), boron arsenide (BAs), silicon carbide (SiC), beryllium oxide (BeO), beryllium sulfide (BeS), aluminum nitride (AlN), aluminum phosphide (AlP), gallium nitride (GaN), gallium phosphide (GaP), aluminum oxide (AlO), graphene, or carbon nano tubes (CNT). In some embodiments, a density of the heat sink fibers 110 in the underfill 108 is greater than approximately 20 vol%, but the disclosure is not limited thereto.

In some embodiments, each of the heat sink fibers 110 has a diameter less than 10 micrometers, but the disclosure is not limited thereto. In some embodiments, the heat sink fibers 110 may have same diameters. In some embodiments, the heat sink fibers 110 may have various diameters. Further, a length of each heat sink fiber 110 is greater than the diameter of each heat sink fiber 110. In some embodiments, the heat sink fibers 110 may be separated from the substrate 102 and from the package component 104. In other embodiments, the heat sink fiber may be in contact with the substrate 102 and/or the package component 104. Further, the heat sink fibers 110 are separated from the connectors 106, as shown in FIGS. 1 to 4. In some embodiments, the heat sink fibers 110 are separated from each other. In other embodiments, the heat sink fibers 110 intersect each other. In such embodiments, the heat sink fibers 110 may intersect to form a net in the underfill 108.

The heat sink fibers 110 are arranged between the substrate 102, the package component 104, and the connectors 106. Referring to FIG. 1, in some embodiments, at least one of the heat sink fibers 110 extends in a direction (i.e., the y direction) substantially perpendicular to a top surface of the substrate 102 or to a bottom surface of the package component 104. In some embodiments, the heat sink fibers 110 may be substantially parallel to each other, but the disclosure is not limited thereto. Further, the heat sink fibers 110 may be arranged along a direction (i.e., the x direction) parallel to the top surface of the substrate 102 or the bottom surface of the package component 104. In some embodiments, spacing distances between adjacent pairs of heat sink fibers 110 may be identical, but the disclosure is not limited thereto. In some embodiments, a spacing distance between an adjacent pair of heat sink fibers 110 may be different from a spacing distance between another adjacent pair of heat sink fibers 110. Still referring to FIG. 1, in some embodiments, when the heat sink fibers 110 extend in the y direction, a direction of heat conduction is substantially perpendicular to the bottom surface of the package component 104 or vertical to the top surface of the substrate 102. In some embodiments, heat H may be dissipated from the package component 104 (usually at a higher temperature during operation) to the substrate 102 (usually at a lower temperature during operation) through the heat sink fibers 110, which serve as dissipation paths in the underfill 108.

Referring to FIG. 2, in some embodiments, at least one of the heat sink fibers 110 extends in a direction (i.e., the x direction) substantially parallel with the top surface of the substrate 102 or with the bottom surface of the package component 104. In such embodiments, the heat sink fibers 110 may be substantially parallel with each other, but the disclosure is not limited thereto. Further, the heat sink fibers 110 may be arranged along a direction (i.e., the y direction) perpendicular to the top surface of the substrate 102 or to the bottom surface of the package component 104. In some embodiments, spacing distances between adjacent pairs of heat sink fibers 110 may be identical, but the disclosure is not limited thereto. In some embodiments, a spacing distance between an adjacent pair of heat sink fibers 110 may be different from a spacing distance between another adjacent pair of heat sink fibers 110. Still referring to FIG. 2, in some embodiments, when the heat sink fibers 110 extend from one of the connectors 108 to another connector 108, a direction of heat conduction is substantially parallel with the bottom surface of the package component 104 or parallel with the top surface of the substrate 102. In some embodiments, heat H may be dissipated from a portion of the package component 104 (usually a hot spot at a higher temperature during operation) to other portions of the package component 104 (usually at a lower temperature during operation) through the heat sink fibers 110, which serve as dissipation paths in the underfill 108.

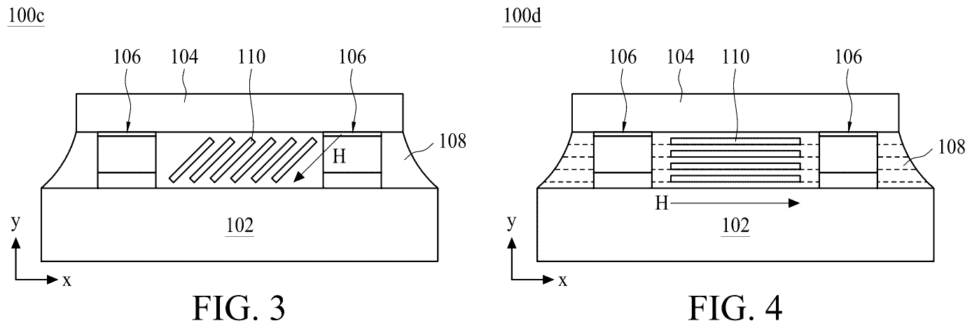

Referring to FIG. 3, in some embodiments, at least one of the heat sink fibers 110 and the top surface of the substrate 102 define an included angle greater than 0 degrees (° and less than 90°. In such embodiments, the heat sink fibers 110 may be parallel with each other, but the disclosure is not limited thereto. In some embodiments, spacing distances between adjacent pairs of the heat sink fibers 110 may be identical, but the disclosure is not limited thereto. In some embodiments, a spacing distance between an adjacent pair of heat sink fibers 110 may be different from a spacing distance between another adjacent pair of heat sink fibers 110. Still referring to FIG. 3, in such embodiments, heat H may be dissipated from the package component 104 (usually at a higher temperature during operation) to the substrate 102 (usually at a lower temperature during operation). Further, heat H may be dissipated from a portion of the package component 104 (usually a hot spot at a higher temperature during operation) to other portions of the package component 104 (usually at a lower temperature during operation) through the heat sink fibers 110, which serve as dissipation paths in the underfill 108.

Referring to FIG. 4, in some embodiments, the underfill 108 may include a plurality of underfill layers, and each underfill layer includes a plurality of heat sink fibers 110 extending in a direction (i.e., the x direction) substantially parallel with the top surface of the substrate 102 or with the bottom surface of the package component 104. In such embodiments, the heat sink fibers 110 may be substantially parallel with each other, but the disclosure is not limited thereto. Further, the heat sink fibers 110 may be arranged along a direction (i.e., the y direction) perpendicular to the top surface of the substrate 102 or the bottom surface of the package component 104. In some embodiments, spacing distances between adjacent pairs of the heat sink fibers 110 may be identical, but the disclosure is not limited thereto. In such embodiments, a spacing distance between adjacent pairs of the heat sink fibers 110 may be equal to a thickness of the underfill layer between such two heat sink fibers 110. In some embodiments, the heat sink fibers 110 in each underfill layer are separated from each other. In some alternative embodiments, the heat sink fibers 110 in each underfill layer intersect each other. In such embodiments, the heat sink fibers 110 may form a net in each of the underfill layers. Still referring to FIG. 4, in some embodiments, heat H may be dissipated from a portion of the package component 104 (usually a hot spot at a higher temperature during operation) to other portions of the package component 104 (usually at a lower temperature during operation) through the heat sink fibers 110, which serve as dissipation paths in the underfill 108.

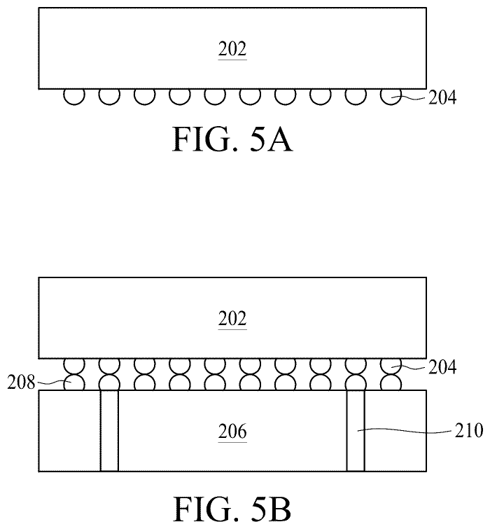

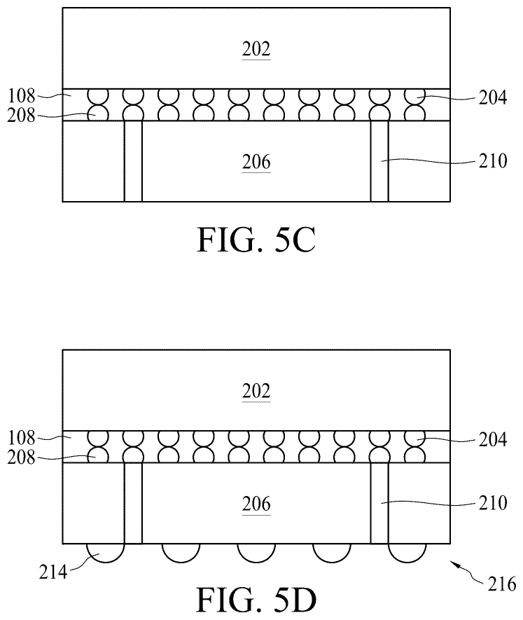

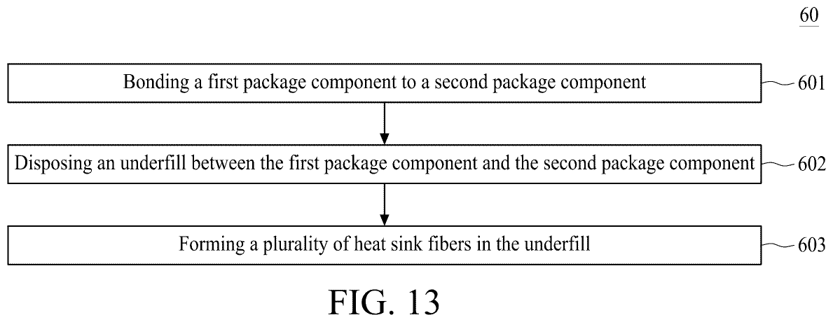

FIGS. 5A to 5D are cross-sectional views of various stages in a formation of a semiconductor package structure in accordance with aspects of the present disclosure in one or more embodiments. The corresponding operations are reflected schematically in a flowchart shown in FIG. 13. In some embodiments, heat sink fibers 110 (not shown) may be disposed in an underfill 108 between two package components. For example but not limited thereto, the heat sink fibers 110 may be disposed in the underfill 108 between two system on a chips (SoCs), or two dies.

Referring to FIG. 5A, in some embodiments, a SoC 202 may be received. The SoC 202 may include a semiconductor die substrate that includes various microelectronic elements (not shown) formed therein, a BEOL interconnect structure (not shown) electrically connected to the various microelectronic elements to form an IC, and a plurality of connectors 204 coupled to the BEOL interconnect structure to provide electrical connections between the IC and external elements.

Referring to FIG. 5B, in some embodiments, another SoC 206 may be received. The SoC 206 may include a semiconductor die substrate that includes various microelectronic elements (not shown) formed therein, a BEOL interconnect structure (not shown) electrically connected to the various microelectronic elements to form an IC, and a plurality of connectors 208 coupled to the BEOL interconnect structure to provide electrical connections between the IC and external elements. In some embodiments, the SoC 206 may further includes a plurality of through substrate via (TSV) 210 disposed therein. In some embodiments, the SoC 202 and the SoC 206 are bonded in a flip chip stacking approach. Further, the connectors 204 of the SoC 202 and the connectors 208 of the SoC 206 are bonded, as shown in FIG. 5B.

Referring to FIG. 5C, in some embodiments, an underfill 108 is formed or injected into gaps between the SoC 202, the SoC 206 and the bonded connectors 204 and 208. Further, a plurality of heat sink fibers 110 are disposed in the underfill 108, though not shown. A configuration and an arrangement of the heat sink fibers 110 in the underfill 108 may be similar to that shown in FIGS. 1 to 4; therefore, repeated description of such details is omitted for brevity.

Still referring to FIG. 5C, in some embodiments, the heat sink fibers 110 are disposed in the underfill 108 during the injection of the underfill 108. In other embodiments, the heat sink fibers 110 are formed after the injection of the underfill 108. Formation of the heat sink fibers 110 is described below.

In some embodiments, the TSVs 210 may be exposed after the forming of the underfill 108 and the heat sink fibers 110, but the disclosure is not limited thereto.

Referring to FIG. 5D, in some embodiments, a plurality of connectors 214 are formed on the SoC 206 a side opposite to where the SoC 202 and the SoC 206 are bonded. The connectors 214 may include controlled collapse of chip connection (C4), but the disclosure is not limited thereto. In some embodiments, an assembly 216 is obtained, and such assembly 216 may be referred to as a package component that is ready to be used in subsequent manufacturing processes.

In some embodiments, the heat sink fibers 110 may improve heat dissipation between the SoC 202 and the SoC 206. In some embodiments, heat may be dissipated from an SoC at a relatively high temperature to another SoC at a relatively low temperature, as shown in FIG. 1. In some embodiments, heat may be dissipated from a hot spot of the SoC 202 and/or the SoC 206 to other portions of the SoC 202 and/or the SoC 206, as shown in FIGS. 2 and 4. In some embodiments, heat may be dissipated from a hot spot of the SoC 202 to a portion of the SoC 206 that is at relatively low temperature, as shown in FIG. 3.

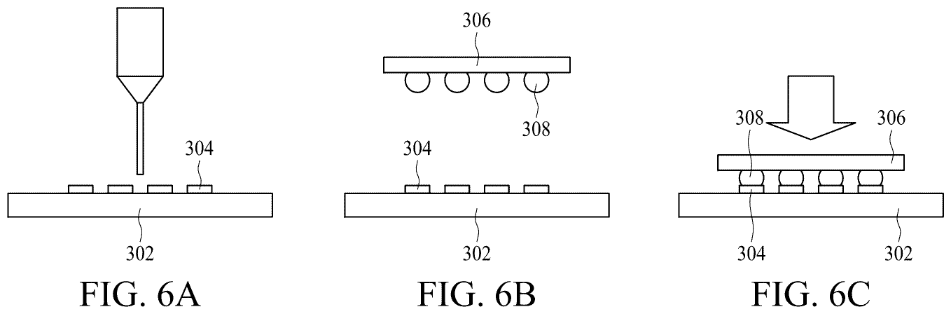

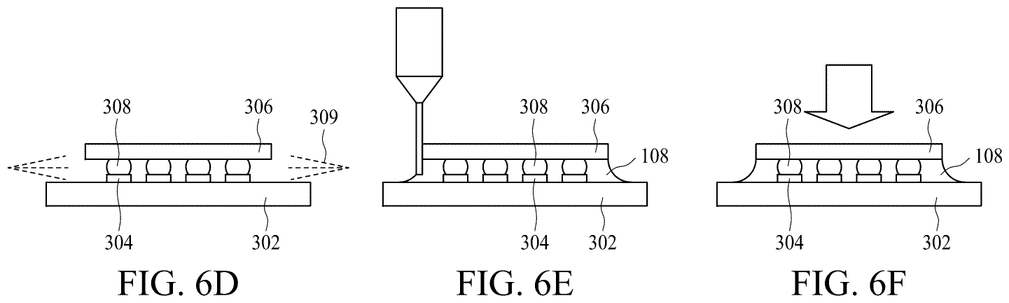

FIGS. 6A to 6F are cross-sectional views of various stages in a formation of a semiconductor package structure in accordance with aspects of the present disclosure in one or more embodiments. The corresponding operations are reflected schematically in a flowchart shown in FIG. 13. In some embodiments, heat sink fibers 110 (not shown) may be disposed in an underfill 108 between two package components. For example, the heat sink fibers 110 may be disposed in the underfill 108 between a chip/die and a substrate such as semiconductor substrate, an interposer substrate or a printed circuit board (PCB) substrate.

Referring to FIG. 6A, in some embodiments, a substrate 302 is received. In some embodiments, the substrate 302 may be a semiconductor substrate that corresponds to the substrate 102 as shown in FIGS. 1 to 4. In some embodiments, the substrate 302 may be an interposer substrate. In other embodiments, the substrate 302 may be a PCB substrate. As shown in FIG. 6A, a plurality of bonding pads 304 are formed over a surface of the substrate 302.

Referring to FIG. 6B, another package component 306 is received. In some embodiments, the package component 306 may be a die that corresponds to the SoC 202 or 206 as shown in FIGS. 5A and 5B. In other embodiments, the package component 306 may be an assembly 216 as shown in FIG. 5D. The package component 306 may be one or more dies, an assembly, or one or more packages that may be used to include a semiconductor package structure with the substrate 302. In some embodiments, the package component 306 includes a plurality of connectors 308, for example but not limited thereto, a plurality of solder balls.

Referring to FIG. 6C, the package component 306 is bonded to the substrate 302. In some embodiments, the connectors 308 (i.e., the C4 bumps) are bonded to the connectors 304 (i.e., the bonding pads). Referring to FIG. 6D, in some embodiments, a cleaning operation may be performed. For example but not limited thereto, the cleaning operation may be performed using a solvent 309 to remove flux after the bonding of the package component 306 to the substrate 302.

Referring to FIG. 6E, in some embodiments, the underfill 108 is formed or injected into gaps between the substrate 302, the die package component 306 and the bonded connectors 304 and 308. Further, a plurality of heat sink fibers 110 are disposed in the underfill 108, though not shown. A configuration and an arrangement of the heat sink fibers 110 in the underfill 108 may be similar to those shown in FIGS. 1 to 4; therefore, repeated description is omitted for brevity.

Still referring to FIG. 6E, in some embodiments, the heat sink fibers 110 are disposed in the underfill 108 during the injection of the underfill 108. In other embodiments, the heat sink fibers 110 are formed after the injection of the underfill 108. The formation of the heat sink fibers 110 is described below.

Referring to FIG. 6F, in some embodiments, after the disposing of the underfill 108 and the forming of the heat sink fibers 110 in the underfill 108, the underfill 108 may be cured using a thermal operation. By curing the underfill 108, the arrangement and placements of the heat sink fibers 110 are fixed.

In such embodiments, the heat sink fibers 110 may improve heat dissipation between the package component 306 and the substrate 302. In some embodiments, heat may be dissipated from the package component 306 at a relatively high temperature to the substrate 302 at a relatively low temperature, as shown in FIG. 1. In some embodiments, heat may be dissipated from a hot spot of the package component 306 to other portions of the package component 306 at a relatively low temperature, as shown in FIGS. 2 and 4. In some embodiments, heat may be dissipated from a hot spot of the die package component to the substrate 302 at a relatively low temperature and to a portion of the package component 306 at a relatively low temperature.

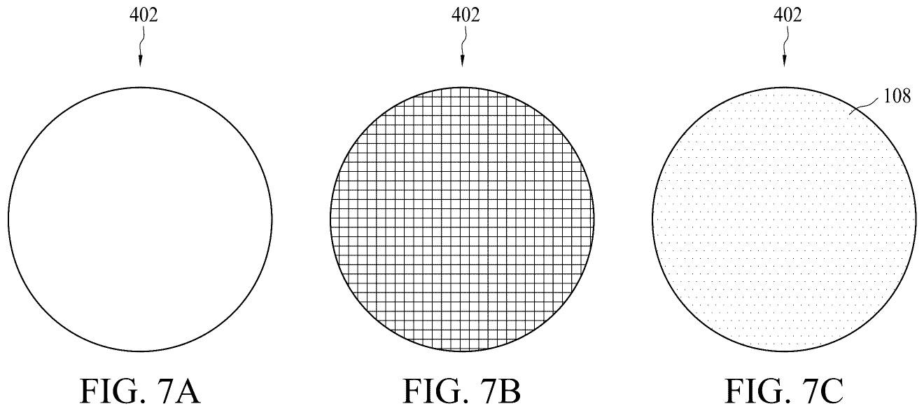

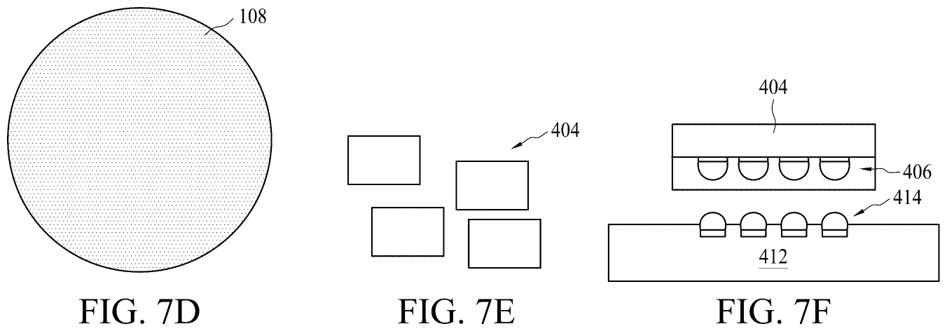

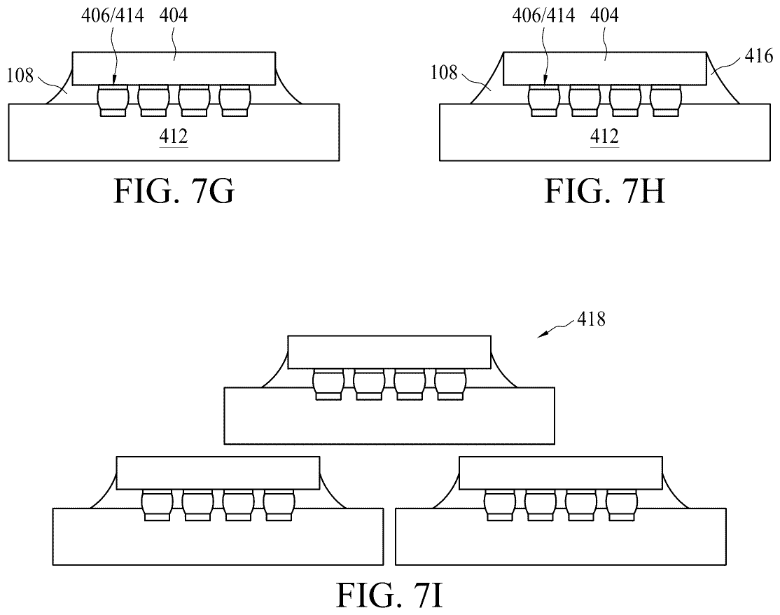

FIGS. 7A to 7I are cross-sectional views of various stages in a formation of a semiconductor package structure in accordance with aspects of the present disclosure in one or more embodiments. The corresponding operations are reflected schematically in a flowchart shown in FIG. 13. In some embodiments, heat sink fibers 110 (not shown) may be disposed in an underfill 108 between two package components. For example, the heat sink fibers 110 may be disposed in the underfill 108 between a chip/die and a semiconductor wafer in wafer-level approaches.

Referring to FIG. 7A, in some embodiments, a wafer 402 is received. In some embodiments, the wafer 402 includes a semiconductor substrate that corresponds to the substrate 102 as shown in FIGS. 1 to 4. In some embodiments, a plurality of dies 404 (shown in FIG. 7E) are formed in the wafer 402. A plurality of connectors 406 (shown in FIG. 7F) are formed for providing electrical connection between microelectronic elements in each die 404 and an external element. In some embodiments, the connectors 406 include copper pillars, but the disclosure is not limited thereto. In some embodiments, a laser grooving may be performed on the wafer 402, as shown in FIG. 7B.

Referring to FIG. 7C, in some embodiments, the underfill 108 is formed over the wafer 402. Further, the underfill 108 covers the connectors 406 (shown in FIG. 7F) and fills gaps between the connectors 406. In some embodiments, the underfill 108 is formed over the wafer using a wafer level underfill (WLUF) approach, but the disclosure is not limited thereto. For example but not limited thereto, an over bump applied resin (OBAR) process may be performed to form the underfill 108 over the connectors 406. Further, a plurality of heat sink fibers 110 are disposed in the underfill 108, though not shown. A configuration and an arrangement of the heat sink fibers 110 in the underfill 108 may be similar to that shown in FIGS. 1 to 4; therefore, repeated descriptions are omitted for brevity.

Still referring to FIG. 7C, in some embodiments, the heat sink fibers 110 are disposed in the underfill 108 during the forming of the underfill 108. In other embodiments, the heat sink fibers 110 are formed after the forming of the underfill 108. In other embodiments, the underfill 108 may include a plurality of underfill layers, and the forming of the underfill layers and the forming of the heat sink fibers 110 can be alternately performed. The formation of the heat sink fibers 110 is described below.

Referring to FIG. 7D, in some embodiments, the underfill 108 undergoes a B-stage curing. For example, a drying solvent may be applied to partially cure the underfill 108. In the B-stage curing, reactions between a resin and a curing agent of the underfill 108 are incomplete. Therefore, the underfill 108 is in a partially cured stage.

Referring to FIG. 7E, in some embodiments, the dies 404 are singulated from the wafer 402. Referring to FIG. 7F, in some embodiments, the die 404 is picked and placed over a wafer 412. In some embodiments, the wafer 412 includes a semiconductor substrate that corresponds to the substrate 102 as shown in FIGS. 1 to 4. A plurality of connectors 414 are formed for providing electrical connection between the wafer 412 and other elements, such as the die 404. As shown in FIG. 7F, the die 404 is aligned with the wafer 412.

Referring to FIG. 7G, the die 404 is bonded to the wafer 412. The underfill 108 fills gaps between the die 404, the wafer 412 and the connectors 406 and 414. Referring to FIG. 7H, in some embodiments, a fillet 416 may be dispensed over the underfill 108 and sidewalls of the die 404. As shown in FIG. 7H, the fillet 416 may cover the sidewalls and/or edges of the die 404 and extends outside a footprint of the die 404 for further protection. The fillet 416 may have an outside surface that slopes up to a bottom surface of the die 404 or to the surface of the wafer 412.

Referring to FIG. 7I, the partially-cured underfill 108 may be pressure-cured in a batch oven. Accordingly, the underfill 108 is completely cured, and the heat sink fibers 110 are fixed in the underfill 108. In some embodiments, the dies 404 and the wafer 412 are further singulated, and thus an assembly 418 is obtained, as shown in FIG. 7I.

In such embodiments, the heat sink fibers 110 may improve heat dissipation between the die 404 and the wafer 412. In some embodiments, heat may be dissipated from the die 404 at a relatively high temperature to the wafer 412 at a relatively low temperature, as shown in FIG. 1. In some embodiments, heat may be dissipated from a hot spot of the die 406 to other portions of the die 404 at a relatively low temperature, as shown in FIGS. 2 and 4. In some embodiments, heat may be dissipated from a hot spot of the die 404 to the wafer 412 at a relatively low temperature and to a portion of the die 404 at a relatively low temperature, as shown in FIG. 3.

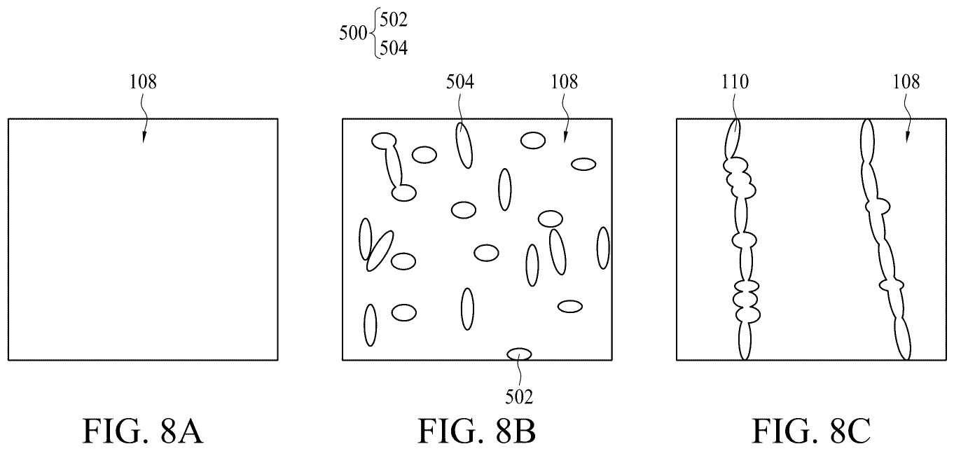

Please refer to FIGS. 8A to 8C, which are schematic drawings illustrating a formation of heat sink fibers in an underfill in accordance with aspects of the present disclosure in one or more embodiments. Referring to FIG. 8A, in some embodiments, a dielectric material is received. The dielectric material is used as an underfill 108. The underfill 108 has three characteristics: (1) low coefficient of thermal expansion (CTE); (2) high glass transition temperature (Tg); and (3) good flow. In some embodiments, a thermal conductivity of the dielectric material with the abovementioned characteristics may be less than 1 W/mK.

Referring to FIG, 8B, in some embodiments, a plurality of fillers 500 are provided and mixed with the underfill 108. The fillers 500 have a thermal conductivity greater than that of the underfill 108. In some embodiments, the fillers 500 include a 2D material 502 such as, for example but not limited thereto, BN. In some embodiments, the fillers 500 include 1D tube 504 such as, for example but not limited thereto, CNT. In other embodiments, the filler materials 500 include both the 2D material 502 and the 1D tube 504, as shown in FIG. 8B.

Referring to FIG. 8C, in some embodiments, the fillers 500 and the underfill 108 are provided to fill gaps between two package components as shown in FIGS. 1 to 4, 5C and 6E. For example, the fillers 500 and the underfill 108 are injected into the gaps between the two package components. In some embodiments, a thermal treatment is then performed on the underfill 108 and the fillers 500. In some embodiments, a temperature of the thermal treatment is less than approximately 450° C., but the disclosure is not limited thereto. Simultaneously, an electric field and/or a magnetic field may be applied to the underfill 108 and the fillers 500. During the thermal treatment, self-aggregation of the fillers 500 occurs. As shown in FIG. 8C, the heat sink fibers 110 are formed by the aggregated fillers 500. The applied electric field or the applied magnetic field helps to improve an efficiency of the aggregation. Further, the applied electric field and/or the applied magnetic field provide magnetic force to create directionality and alignment of the heat sink fibers 110 as shown in FIG. 8C. In some embodiments, the directionality of the heat sink fibers 110 may be obtained by injection. In such embodiments, when injecting both the underfill 108 and the heat sink fibers 110 between the two package components, shear force caused by the injection may force the heat sink fibers 110 obtain a direction that is parallel with an injection direction, as shown in FIG. 8C. Accordingly, after the thermal treatment and the applying of the electric field and/or the magnetic field, or after the thermal treatment and the injection, the heat sink fibers 110 may extend in a direction. Further, the heat sink fibers 110 formed by the 2D materials 502 and the heat sink fibers 110 formed by the 1D tubes 504 are separated from each other.

As shown in FIGS. 1 and 8C, in some embodiments, at least one of the heat sink fibers 110 is forced to extend in a direction substantially perpendicular to surfaces of the two package components. Further, the heat sink fibers 110 are forced and arranged in a direction substantially parallel with the surfaces of the two package components. In other embodiments, by applying the electric field and/or the magnetic field to the heat sink fibers 110, at least one of the heat sink fibers 110 is forced to extend in a direction substantially parallel to the surfaces of the two package components. Further, the heat sink fibers 110 are forced and arranged in a direction substantially perpendicular to the surfaces of the two package components, as shown in FIG. 2. In some other embodiments, at least one of the heat sink fibers 110 is forced to extend in a direction such that the at least one of the heat sink fibers 110 and a surface of one of the two package components form an included angle greater than 0° and less than 90°. Further, the heat sink fibers 110 are forced to be parallel with each other, as shown in FIG. 3.

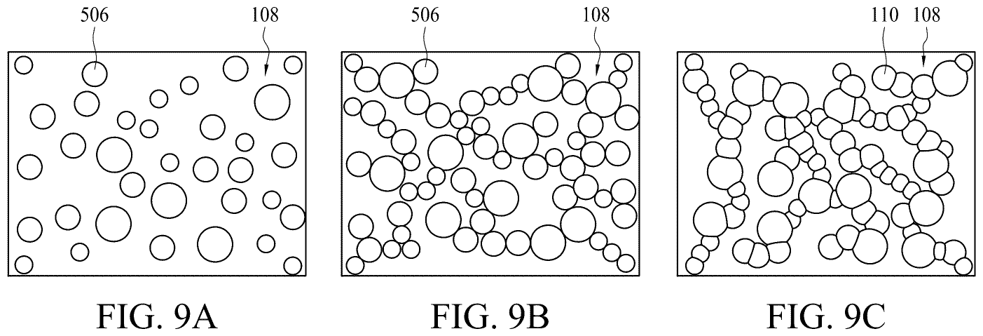

Please refer to FIGS. 9A to 9C, which are schematic drawings illustrating a formation of heat sink fibers in an underfill in accordance with aspects of the present disclosure in one or more embodiments. Referring to FIG. 9A, in some embodiments, a dielectric material is received. The dielectric material is used as the underfill 108 as mentioned above. In some embodiments, a plurality of fillers 506 are provided and mixed with the underfill 108. The fillers 506 have a thermal conductivity greater than that of the underfill 108. In some embodiments, the fillers 506 include ceramic material or porous ceramic material. As shown in FIG. 9A, the fillers 506 may dispersed in the underfill 108 as individual particles.

Referring to FIG. 9B, in some embodiments, the fillers 506 and the underfill 108 are provided to fill gaps between two package components as shown in FIGS. 1 to 4, 5C and 6E. For example, the fillers 506 and the underfill 108 are injected into the gaps between the two package components. In some embodiments, an electromagnetic field is applied to the underfill 108 and the fillers 506. In such embodiments, the fillers 506 start to sinter, as shown in FIG. 9B.

Referring to FIG. 9C, accordingly, neighboring particles are bonded to form heat sink fibers 110, and the heat sink fibers 110 intersect each other to form a net having chemically bonded boundaries. In some embodiments, the electromagnetic field also creates a directionality of the net formed by the heat sink fibers 110. In such embodiments, the nets made of the heat sink fibers 110 are self-arranged by a shear force from the injection or by a magnetic force from the electromagnetic field. For example, referring to FIGS. 1 and 9C, the heat sink fibers 110 may form a first net oriented in a first plane perpendicular to a surface of one of the two package components, a second net oriented in a second plane perpendicular to the surface of the one of the two package components, and an N^{th} net oriented in an N^{th} plane perpendicular to the surface of the one of the two package components. In such embodiments, in a cross-sectional view, the nets formed of the heat sink fibers 110 in the many planes may be arranged in a direction substantially parallel with the surface of the one of the two package components, as shown in FIG. 1.

Referring to FIGS. 2 and 9C, in some embodiments, the heat sink fibers 110 may form a first net oriented in a first plane parallel with a surface of one of the two package components, a second net oriented in a second plane parallel with the surface of the one of the two package components, and an N^{th} net oriented in an N^{th} plane parallel with the surface of the one of the two package components. In such embodiments, in a cross-sectional view, the nets made of the heat sink fibers 110 in the many planes may be arranged in a direction substantially perpendicular to the surface of the one of the two package components, as shown in FIG. 2.

As shown in FIGS. 3 and 9C, in some embodiments, at least one of the nets made of the heat sink fibers 110 in the many planes and the surface of the one of the package components may form an included angle greater than 0° and less than 90°. Further, the nets made of the heat sink fibers 110 in the many planes are forced to be parallel with each other, as shown in FIG. 3.

In some embodiments, after the disposing of the underfill 108 between the two package components and the forming of the heat sink fibers 110, a thermal treatment may be performed to cure the underfill 108 and fix the placements of the heat sink fibers 110 or the nets formed of the heat sink fibers 110.

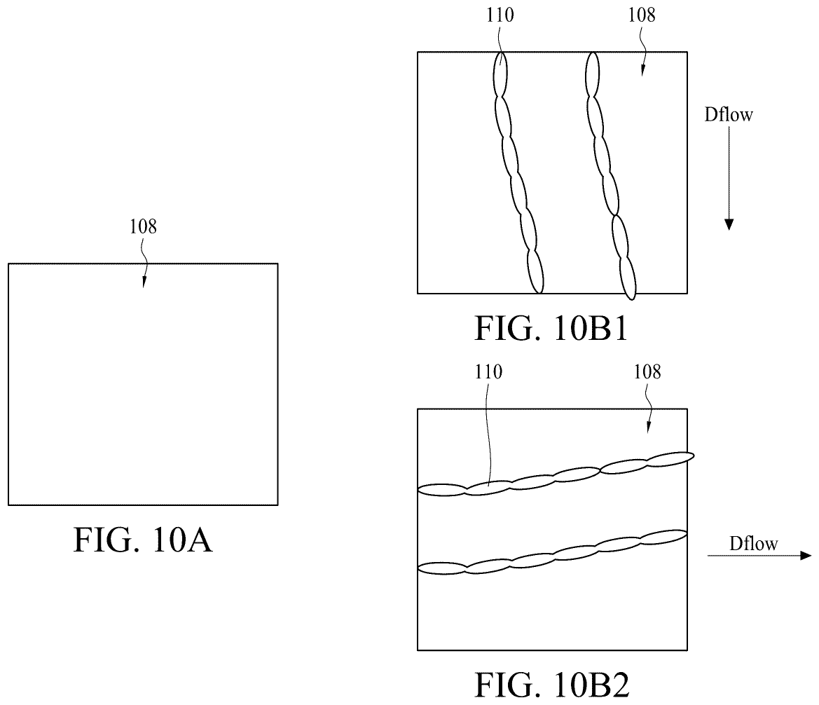

Please refer to FIGS. 10A, 10B1 and 10B2, which are schematic drawings illustrating a formation of heat sink fibers 110 in an underfill 108 in accordance with aspects of the present disclosure in one or more embodiments. In some embodiments, the underfill 108 is injected into gas between two package components. In such embodiments, the underfill 108 may be formed or provided free of heat sink fibers 110, as shown in FIG. 10A.

Referring to FIG. 10B1 and 10B2, in some embodiments, the heat sink fibers 110 are injected into the underfill 108 after the forming of the underfill 108. In some embodiments, an injection molding is provided. In such embodiments, the heat sink fibers 110 are injected into the underfill 108 through a mold and a nozzle, and a shear force caused by the injection tends to cause the heat sink fibers 110 assume a direction. In some embodiments, the heat sink fibers 110 may be separated from each other and may extend in a direction parallel with an injection direction or a flow direction D_{flow}, such that at least one of the heat sink fibers 110 may extend in a direction substantially perpendicular to a surface of one of the package components, as shown in FIGS. 1 and 10B1. In other embodiments, at least one of the heat sink fibers 110 may extend in a direction substantially parallel with a surface of one of the package components, as shown in FIGS. 2 and 10B2.

Additionally, the heat sink fibers 110 may be substantially parallel with each other.

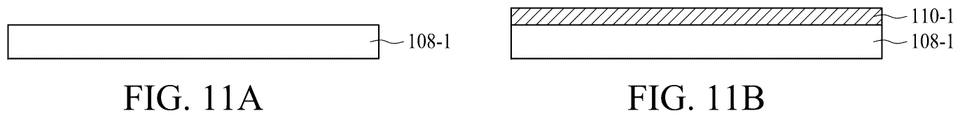

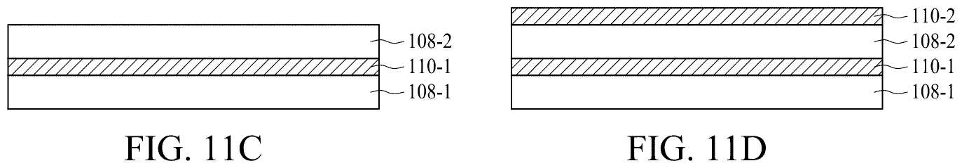

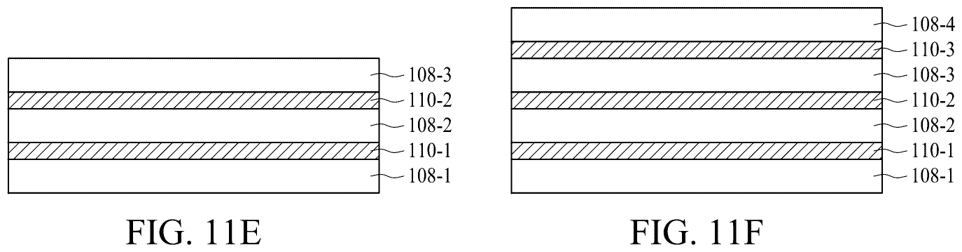

Please refer to FIGS. 11A to 11F, which are schematic drawings illustrating a formation of heat sink fibers in an underfill in accordance with aspects of the present disclosure in one or more embodiments. In some embodiments, the underfill 108 may include a plurality of underfill layers, and the heat sink fibers 110 may be formed in each of the underfill layers. Referring to FIG. 11A, in some embodiments, a first underfill layer 108-1 may be formed on a surface of a package component, for example, a surface of a wafer 402 (shown in FIG. 7A). Subsequently, referring to FIG. 11B, a plurality of heat sink fibers 110-1 are formed over the first underfill layer 108-1. In some embodiments, the heat sink fibers 110-1 can be formed by a chemical vapor deposition (CVD), but the disclosure is not limited thereto. In some embodiments, the heat sink fibers 110-1 may extend in a direction parallel with the surface of the package component, and the heat sink fibers 110-1 may extend substantially parallel with each other. In some alternative embodiments, the heat sink fibers 110-1 may intersect each other to form a net over the first underfill layer 108-1.

Referring to FIG. 11C, a second underfill layer 108-2 is formed over the heat sink fibers 110-1. Referring to FIG. 11D, a plurality of heat sink fibers 110-2 are formed over the second underfill layer 108-2. In some embodiments, the heat sink fibers 110-2 can be formed by a CVD, but the disclosure is not limited thereto. In some embodiments, the heat sink fibers 110-2 may extend in a direction parallel with the surface of the package component, and the heat sink fibers 110-2 may extend substantially parallel with each other. In some alternative embodiments, the heat sink fibers 110-2 may be intersect each other to form a net over the second underfill layer 108-2.

Referring to FIG. 11E, a third underfill layer 108-3 is formed over the heat sink fibers 110-2. Referring to FIG. 11F, a plurality of heat sink fibers 110-3 are formed over the third underfill layer 108-3. In some embodiments, the heat sink fibers 110-3 can be formed by a CVD, but the disclosure is not limited thereto. In some embodiments, the heat sink fibers 110-3 may extend in a direction parallel with the surface of the package component, and the heat sink fibers 110-3 may extend substantially parallel with each other. In some alternative embodiments, the heat sink fibers 110-3 may be intersect each other to form a net over the third underfill layer 108-3. A fourth underfill layer 108-4 may be formed over the heat sink fibers 110-3. Accordingly, multi-layered underfill 108 including the first to fourth underfill layers 108-1 to 108-4 with a plurality of heat sink fibers in multiple planes is obtained, as shown in FIGS. 11F and 4. In other words, the heat sink fibers 110-1 to 110-3 in the multiple planes are sandwiched or embedded in the multi-layered underfill 108. It should be noted that a quantity of the underfill layers and a quantity of the planes where the heat sink fibers 110-1 to 110-3 are formed are presented as an example here, and such quantities can be modified according to product designs.

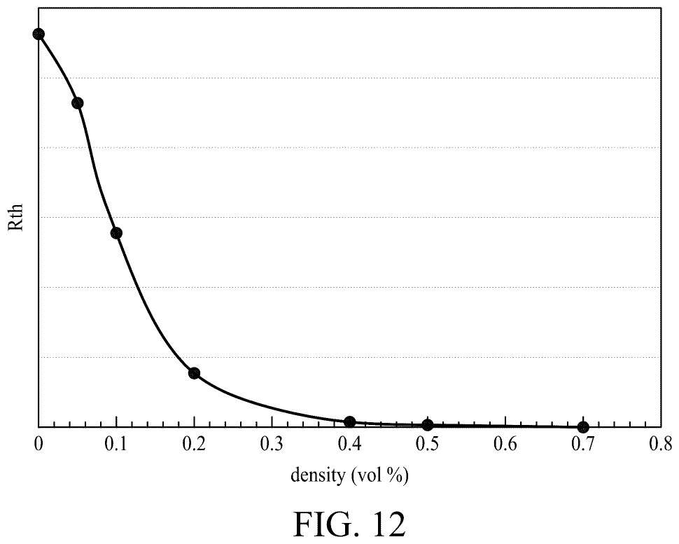

Please refer to FIG. 12, which is a diagram illustrating a simulation of a thermal resistance and a density of heat sink fibers in an underfill. In FIG. 12, the abscissa represents a density of the heat sink fibers 110 in the underfill 108, and the ordinate represents a thermal resistance (Rm) of the underfill 108 including the heat sink fibers 110. As shown in FIG. 12, it is found that the thermal resistance can be unexpectedly reduced when the density (i.e., a volume percentage, vol%) of the heat sink fibers 110 is greater than approximately 20%.

Referring to FIG. 13, a method for forming a semiconductor package structure 60 is provided. While the disclosed method 60 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 601, a first package component and a second package component are received and bonded. In some embodiments, the first and second package components 202 and 206 may be bonded as shown in FIG. 5B. In some embodiments, the first and second package components 302 and 306 may be bonded as shown in FIG. 6C. In some embodiments, the first and second package components 404 and 412 may be bonded as shown in FIG. 7G.

In operation 602, an underfill is disposed between the first package component and the second package component. In some embodiments, the underfill 108 may be disposed between the first package component 202 and the second package component 206 by injection, as shown in FIG. 5C. In some embodiments, the underfill 108 may be disposed between the first package component 302 and the second package component 306 by injection, as shown in FIG. 6E. In such embodiments, the underfill 108 is disposed after the bonding of the first package component and the second package component. In some embodiments, the underfill 108 may be disposed prior to the bonding of the first package component 404 and the second package component 412, as shown in FIG. 7F. In such embodiments, the underfill 108 may cover connectors 406 of the first package component 404.

In operation 603, a plurality of heat sink fibers are formed in the underfill. In some embodiments, operation 602 and operation 603 can be simultaneously performed. In such embodiments, the heat sink fibers 110 may be formed with the disposing of the underfill 108 as shown in FIGS. 8A to 8C and FIGS. 9A to 9C. In some embodiments, operation 603 is performed after operation 602. In such embodiments, the heat sink fibers 110 are formed by injection into the underfill 108, as shown in FIGS. 10A, 10B1 and 10B2.

In some embodiments, the underfill 108 may include a plurality of underfill layers 108-1 to 108-4. Further, the forming of the underfill layers 108-1 to 108-4 and the forming of the heat sink fibers 110-1 to 110-3 can be periodically performed, as shown in FIGS. 11A to 11F. In such embodiments, operation 602 and operation 603 may be performed prior to the bonding of the first package component 404 and the second package component 412 as shown in FIGS. 7F and 7G.

In accordance with some embodiments, the present disclosure provides a scheme for improving heat dissipation in semiconductor package structures and methods of forming the semiconductor package structures. In some embodiments, heat sink fibers are provided and embedded in an underfill. The heat sink fibers include material having a thermal conductivity greater than that of the underfill and thus serves as dissipation paths. Accordingly, heat can be dissipated through the heat sink fibers and thus heat dissipation of the semiconductor package structure is improved.

In some embodiments, a semiconductor package structure is provided. The semiconductor package structure includes a first package component, a second package component disposed over the first package component, a plurality of connectors between the first package component and the second package component, an underfill between the first package component and the second package component and surrounding the plurality of connectors, and a plurality of heat sink fibers in the underfill. A thermal conductivity of the plurality of heat sink fibers is greater than a thermal conductivity of the underfill.

In some embodiments, a semiconductor package structure is provided. The semiconductor package structure includes a first package component, a second package component over the first package component, a plurality of connectors between the first package component and the second package component, a first underfill layer, a second underfill layer and a plurality of heat sink fibers between the first underfill layer and the second underfill layer. The first underfill layer and the second underfill layer are disposed between the first package component and the second package component, and surround the plurality of connectors. A thermal conductivity of the plurality of heat sink fibers is greater than a thermal conductivity of the first underfill layer, and greater than a thermal conductivity of the second underfill layer.

In some embodiments, a method for forming a semiconductor package structure is provided. The method includes following operations. A first package component is bonded to a second package component. An underfill is disposed between the first package component and the second package component. A plurality of heat sink fibers are formed in the underfill. A thermal conductivity of the plurality of heat sink fibers is greater than a thermal conductivity of the underfill.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure comprising:
a first package component;
a second package component disposed over the first package component;
a plurality of connectors between the first package component and the second package component;
an underfill between the first package component and the second package component and surrounding the plurality of connectors; and
a plurality of heat sink fibers in the underfill,
wherein a thermal conductivity of the plurality of heat sink fibers is greater than a thermal conductivity of the underfill.

2. The semiconductor package structure of claim 1, wherein at least one of the plurality of heat sink fibers extends in a direction substantially perpendicular to a surface of the first package component or a surface of the second package component.

3. The semiconductor package structure of claim 1, wherein at least one of the plurality of heat sink fibers extends in a direction substantially parallel with a surface of the first package component or a surface of the second package component.

4. The semiconductor package structure of claim 1, wherein the plurality of heat sink fibers intersect in the underfill.

5. The semiconductor package structure of claim 1, wherein the plurality of heat sink fibers are separated from each other.

6. The semiconductor package structure of claim 1, wherein the plurality of heat sink fibers are separated from the plurality of connectors.

7. The semiconductor package structure of claim 1, wherein the plurality of heat sink fibers comprise 2D materials.

8. The semiconductor package structure of claim 1, wherein the plurality of heat sink fibers comprise diamond, boron nitride (BN), boron phosphide (BP), boron arsenide (BAs), silicon carbide (SiC), beryllium oxide (BeO), beryllium sulfide (BeS), aluminum nitride (AlN), aluminum phosphide (AlP), gallium nitride (GaN), gallium phosphide (GaP), aluminum oxide (AlO), graphene, and/or carbon nano tubes (CNT).

9. The semiconductor package structure of claim 1, wherein the diameter of the heat sink fibers is less than 10 micrometers.

10. The semiconductor package structure of claim 1, wherein a density of the plurality of heat sink fibers in the underfill is greater than approximately 20%.

11. A semiconductor package structure comprising:
a first package component;
a second package component disposed over the first package component;
a plurality of connectors between the first package component and the second package component;
a first underfill layer between the first package component and the second package component and surrounding the plurality of connectors;
a second underfill layer between the first package component and the second package component and surrounding the plurality of connectors; and
a plurality of heat sink fibers between the first underfill layer and the second underfill layer,
wherein a thermal conductivity of the plurality of heat sink fibers is greater than a thermal conductivity of the first underfill layer and greater than a thermal conductivity of the second underfill layer.

12. The semiconductor package structure of claim 11, wherein the plurality of heat sink fibers are separated from the plurality of connectors.

13. The semiconductor package structure of claim 11, wherein the plurality of heat sink fibers are separated from each other.

14. The semiconductor package structure of claim 11, wherein the plurality of heat sink fibers intersect each other.

15. The semiconductor package structure of claim 11, wherein the plurality of heat sink fibers comprise 2D materials.

16. The semiconductor package structure of claim 11, wherein the plurality of heat sink fibers comprise diamond, boron nitride, boron phosphide, boron arsenide, silicon carbide, beryllium oxide, beryllium sulfide, aluminum nitride, aluminum phosphide, gallium nitride, gallium phosphide, aluminum oxide, graphene, and/or carbon nano tubes.

17. A method for forming a semiconductor package structure, comprising:
bonding a first package component to a second package component;
disposing an underfill between the first package component and the second package component; and
forming a plurality of heat sink fibers in the underfill,
wherein a thermal conductivity of the plurality of heat sink fibers is greater than a thermal conductivity of the underfill.

18. The method of claim 17, wherein the forming of the plurality of heat sink fibers in the underfill further comprises:
injecting a plurality of fillers into the underfill;
disposing the underfill and the plurality of fillers between the first package component and the second package component;
applying an electric field or a magnetic field to the underfill; and
performing a thermal treatment.

19. The method of claim 17, wherein the forming of the plurality of heat sink fibers in the underfill further comprises injecting the plurality of heat sink fibers into the underfill after the disposing of the underfill between the first package component and the second package component.

20. The method of claim 17, wherein the forming of the plurality of heat sink fibers in the underfill further comprises:
forming a first underfill layer;
forming the plurality of heat sink fibers over the first underfill layer; and
forming a second underfill layer over the plurality of heat sink fibers.
